(19) United States
(12) Patent Application Publication
(10) Pub. No.: US 2025/0275204 A1
(43) Pub. Date: Aug. 28, 2025

(54) GATE-ALL-AROUND FIELD EFFECT TRANSISTOR WITH VARIABLE CHANNEL GEOMETRIES

(71) Applicant: International Business Machines Corporation, Armonk, NY (US)

(72) Inventors: Mohammad Hasanuzzaman, Niskayuna, NY (US); Julien Frougier, Albany, NY (US); Shogo Mochizuki, Mechanicville, NY (US); Andres Bryant, Burlington, VT (US); Reinaldo Vega, Mahopac, NY (US); Karsu Kilic, Palo Alto, CA (US); Curtis Scott Durfee, Schenectady, NY (US); Andrew Gaul, Halfmoon, NY (US); Andrew Mark Greene, Slingerlands, NY (US); Nicolas Jean Loubet, Guilderland, NY (US); Pietro Montanini, Albany, NY (US); Christopher D. Sheraw, Altamont, NY (US); William Murphy Parkin, Beacon, NY (US); Oleg Gluschenkov, Tannersville, NY (US)

(21) Appl. No.: 18/587,923

(22) Filed: Feb. 26, 2024

(51) Int. Cl. H01L 29/10; H01L 21/8234; H01L 27/088; H01L 29/06; H01L 29/417; H01L 29/423; H01L 29/66; H01L 29/775; H01L 29/786

(52) U.S. Cl. CPC H10D 62/292; H10D 30/014; H10D 30/43; H10D 30/6735; H10D 30/6757; H10D 62/121; H10D 64/258; H10D 84/0128; H10D 84/038; H10D 84/83

(57) ABSTRACT

A gate-all-around transistor includes a gate structure having sidewalls; a first and a second gate spacer positioned laterally on each sidewall, wherein the gate structure has a gate length between the sidewalls of the gate structure, the gate length having a midpoint; a first inner spacer under the first gate spacer; and a second inner spacer under the second gate spacer. A channel layer extends from below the first inner spacer, across the gate length to below the second inner spacer. The channel layer includes a first region having a first thickness and located below each of the gate spacers; and a second region having a continuously variable thickness, the second region located laterally between the first regions and being symmetrical in reference to the midpoint of the gate length.

### BACKGROUND

The present disclosure generally relates to the fabrication of integrated circuits, and, more particularly, to various methods of forming a nano-sheet transistor device and the resulting device.

Gate-all-around (“GAA”) nanosheet transistors include a plurality of vertically spaced-apart sheets of channel layers separated from each other by inner spacers. A gate structure for the device is positioned around each of these spaced-apart channel layers. GAA transistors have superior gate control and higher short channel effect (“SCE”) suppression ability than fin-type field effect transistors (FinFETs) due to the gate surrounding the channels. GAA nanosheet transistors also provide higher “ON” current and improved electrostatic control over FinFETs. Nevertheless, there is a constant demand to improve the functionality of integrated circuits.

### BRIEF SUMMARY

Principles of the invention provide techniques for a gate-all-around field effect transistor with variable channel geometries. In one aspect, an exemplary gate-all-around transistor includes a gate structure having sidewalls, a first and a second gate spacer positioned laterally on each sidewall, in which the gate structure has a gate length between the sidewalls of the gate structure, the gate length having a midpoint, a first inner spacer under the first gate spacer, a second inner spacer under the second gate spacer, a channel layer extending from below the first inner spacer, across the gate length to below the second inner spacer. The channel layer including a first region having a first thickness and located below each of the gate spacers and a second region having a continuously variable thickness, the second region located laterally between the first regions and being symmetrical in reference to the midpoint of the gate length.

An aspect of an exemplary method of forming a semiconductor structure includes forming a nanostack on a substrate in which each nanostack comprises alternating layers of a sacrificial material and a channel layer, etching the nanosheet stack to form at least two adjacent, parallel nanostack fins, forming a shallow trench isolation region in the substrate and between the nanostack fins, forming a dummy gate fin over and perpendicular to the nanostack fins, forming a gate spacer around the dummy gate fin to create an exposed portion of the substrate, removing portions of the sacrificial material in the nanostack fins to create a recess, forming an inner spacer in the recess, forming source-drain regions on the exposed portion of the substrate on either side of the dummy gate fin and in contact with the channel layer, forming a planarized middle of the line dielectric layer over the substrate, removing the dummy gate fin and the sacrificial material remaining in the nanostack fin to create a gate cavity resulting in an exposed portion of the channel layer, trimming the exposed portion of the channel layer in the gate cavity to create a first region of the channel layer under the inner spacer, a second region of the channel layer laterally in contact with the first region and having a curvature, and a third region of the channel layer laterally in contact with the second region, in which a first region thickness of the channel layer is greater a third region thickness of the channel layer, forming a gate structure in the gate cavity; and forming contacts to the source-drain region and gate structure.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 Depicts a top-down layout of transistors according to aspects of the invention;

FIGS. 2A-2B illustrate an exemplary variable thickness channel layer and figures of merit according to aspects of the invention;

FIGS. 3A-3B illustrate another exemplary variable thickness channel layer according to aspects of the invention;

FIGS. 4A-4D through 15A-15D illustrate a method of making a GAA transistor having a variable thickness channel layer and a self-aligned isolation layer according to aspects of the invention; and

FIGS. 16A-16D through 21A-21D illustrate a method of making a GAA transistor having a variable thickness channel layer without a self-aligned isolation layer according to aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary gate-all-around transistor includes a gate structure 106 having sidewalls 107, a first and a second gate spacer 108 positioned laterally on each sidewall 107, in which the gate structure has a gate length 109 between the sidewalls 107 of the gate structure 106, the gate length 109 having a midpoint 109-M, a first inner spacer 120 under the first gate spacer 108, a second inner spacer 120 under the second gate spacer 108, a channel layer 114 extending from below the first inner spacer 120, across the gate length 109 to below the second inner spacer 120. The channel layer 114 including a first region 130 having a first thickness 131 and located below each of the gate spacers 108 and a second region 132 having a continuously variable thickness portion 133, the second region 132 located laterally between the first regions 130 and being symmetrical in reference to the midpoint 109-M of the gate length 109. Technical benefits of a varying thickness channel layer include enabling tuning of transistor performance.

Optionally, the channel layer can further include a third region 136 having a third thickness 137 less than the first thickness 131, the third region 136 being located at a midpoint 109-M of the gate length 109, with each end of the third region 136 being laterally adjacent the second region 132, the third region having a non-variable thickness. In a further option, a length of the second region 132 is 49% to 2% of the gate length 109. Technical benefits of having a thin third region is that it reduces channel thickness thereby improving short channel effects. In yet another option, the curvature can be 0 to 90 degrees. Technical benefits of curvature adjustment is that it provides further fine tuning of the transistor.

Continuing with options, the first region 130, the second region 132 and the third region 136 can be the same material. The same material can be silicon. The same material can be silicon germanium having uniform germanium concentration. The same material can be silicon germanium having variable germanium concentrations. Further optionally, the concentration of germanium in the first region 130 can be less than concentration of germanium in the third region 136. In another option, the first region 130 is silicon and while the second region 132 and third regions 136 are silicon germanium. In yet another option, the germanium concentration in the third region 136 can be greater than the germanium concentration in the second region 132. Also, optionally, the germanium concentration in the third region 136 can be equal to the germanium concentration in the second region 132. Technical benefits of being able to control germanium concentration, placement and uniformity include fine tuning device transport behavior as well as to control junction position.

In optional further aspects, the gate structure 106 comprises a gate conductor 106A, and a gate dielectric 106B in which the gate structure 106 wraps the channel layer exposed in the gate length 109. Here, optionally, an inner spacer 120 can be located under the first region 130 of the channel layer 114, in which the gate dielectric 106B is between the inner spacer 120 and the channel layer's 114 first region 130. Recessing the extension region and having dielectric under the inner spacer will reduce the inner fringe capacitance (thus reducing overlap capacitance) as well as will reduce device leakage since nanosheet thickness is reduced in inner spacer region.

In optional further aspects, the exemplary gate-all-around transistor also includes a flat portion 134 of the second region 132, wherein the flat portion contacts the first region 130 of the channel layer 114 while the continuously variable thickness portion 133 is in contact with the flat portion 134. Shaping the channel layer allows for more tuning of the transistor.

In optional further aspects, the exemplary gate-all-around transistor also includes a substrate 116 having an upper surface 160, a source-drain region 110 on either side of the channel layer 114, an inner spacer 120 (in which the inner spacer includes an outer surface 120-O in contact with the source-drain region 110 and located under the gate spacer 108; and an inner surface 120-I in contact with the gate structure 106), a self-aligned isolation layer 118 having a top surface, a bottom surface and edge surface 118-E (in which the top surface is in contact with the inner spacer 120 and the gate structure 106, the bottom surface is in contact with the upper surface 160 of the substrate 116, and the edge surface 118-E is vertically aligned with the outer surface of the inner spacer 120-O), a second transistor; and a shallow trench isolation region 104 separating the transistor and the second transistor. The second transistor includes a second self-aligned isolation layer 118 and a second gate structure in which a top surface of the second self-aligned isolation layer 118 is in contact with the second gate structure 106 and the bottom surface is in contact with the upper surface 160 of the substrate 116, and in which the upper surface 160 of the substrate 116 is higher than a top surface 104-T of the shallow trench isolation region 104. A technical benefit of a self-aligned isolation layer is a manufacturable structure having reduced leakage.

An aspect of an exemplary method of forming a semiconductor structure includes forming a nanostack 145 on a substrate 116 in which each nanostack 145 comprises alternating layers of sacrificial material 143 and a channel layer 114, etching the nanosheet stack to form at least two adjacent, parallel nanostack fins 102, forming a shallow trench isolation region 104 in the substrate 116 and between the nanostack fins 102, forming a dummy gate 147 over and perpendicular to the nanostack fins 102, forming a gate spacer 108 around the dummy gate 147 to create an exposed portion of the substrate 116, removing portions of the sacrificial material 143 in the nanostack fins 102 to create a recess, forming an inner spacer 120 in the recess, forming source-drain regions 110 on the exposed portion of the substrate on either side of the dummy gate 147 and in contact with the channel layer 114, forming a planarized middle of the line dielectric layer 155 over the substrate, removing the dummy gate 147 and the sacrificial material 143 remaining in the nanostack fin 102 to create a gate cavity 157 resulting in an exposed portion of the channel layer 114, trimming the exposed portion of the channel layer 114 in the gate cavity 157 to create a first region 130 of the channel layer 114 under the inner spacer 120, a second region 132 of the channel layer 114 laterally in contact with the first region 130 and having a curvature, and a third region 136 of the channel layer 114 laterally in contact with the second region 132, in which a first region thickness 131 of the channel layer 114 is greater a third region thickness 137 of the channel layer 114, forming a gate structure 106 in the gate cavity 157; and forming contacts 122 to the source-drain region 110 and gate structure 106. Technical benefits are a method of making tunable transistor having improved short channel effects.

Optionally, the nanostack 145 also includes a bottom sacrificial layer 141 in contact with the substrate 116, and the method further includes removing the bottom sacrificial layer 141 to form a bottom cavity 150 below the nanostack fin 102 and above the substrate 110, and in which forming the gate spacers 108 includes filling the bottom cavity 150 with a gate spacer material and etching the gate spacer material to form a self-aligned isolation layer 118 between the nanostack fin 102 and the substrate 160. A technical benefit is a robust and cost-effective way to build a structure with reduced leakage.

In another option, the method further includes removing a portion of the channel layer 114 from under the inner spacers 120 to form an expanded gate cavity 137, and forming a gate dielectric 106B in the expanded gate cavity. A technical benefit is a larger manufacturing process widow.

In yet another option, after trimming the channel layer 114, the method further includes converting at least a portion of the channel layer 114 in a first nanostack fin 102 to silicon germanium while the channel layers 114 in a second nanostack are masked. A technical benefit is the creating of opposite polarity transistors without lattice matching or integration concerns of the initial nanostack layer.

Techniques as disclosed herein can provide substantial beneficial technical effects. Some embodiments may not have these potential advantages and these potential advantages are not necessarily required of all embodiments. By way of example only and without limitation, one or more embodiments can provide one or more of:

Allow further scaling, enhanced yield, and/or enhanced reliability for semiconductor structures using GAA nanosheet transistors:
by creating a larger space between sheets allowing threshold voltage (Vt) tuning.
by reducing channel thickness (Tsi) allowing improved short channel effects (SCE) control.
by manipulating channel shape allowing FET performance tuning.
by allowing nanosheet integration while preventing pinch-off of adjacent gates during inner spacer formation.

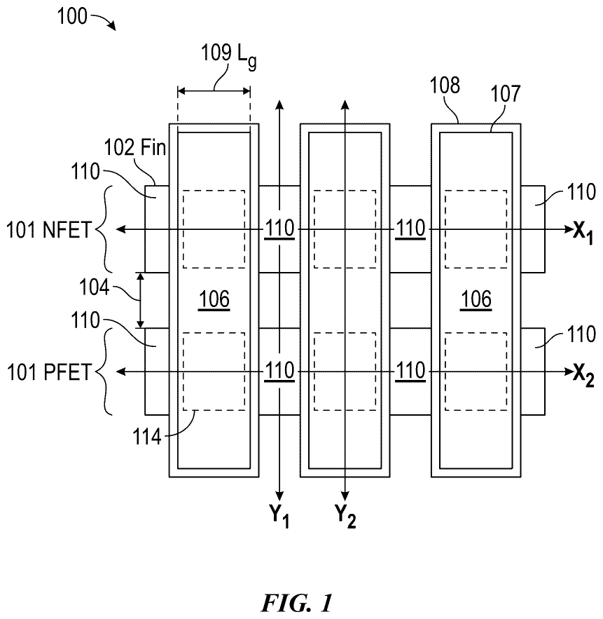

One or more embodiments advantageously provide transistors that can be tuned to exhibit different performance characteristics (e.g. threshold voltages, off-state leakage current, power consumption, etc.). Aspects of the invention provide techniques for trimming channel material in a GAA nanosheet transistor for performance fine tuning of the transistor. Referring to FIG. 1, a top-down layout for a semiconductor structure 100 including GAA field effect transistors 101 (e.g. NFET and PFET) is shown. Here, a pair of semiconductor fins 102 running in the X₁ and X₂ directions serve as the active area of the GAA transistors 101, which in the shown embodiment, are an NFET and PFET, but could be any combination of N or P transistors. Separating the two GAA FETS is a shallow trench isolation region 104. Running perpendicular to the fins 102 are the gate structures 106 having sidewalls 107 surrounded by gate spacer 108. The gate length 109 (“L_{g}”) is the distance between the gate spacers 108 On either side of gate structures 106 in the fin 102 are source-drain regions 110. Located at the intersection of the fin 102 and gate structure 106, and embedded below the upper surface of the gate structure 106 are stacked channel layers 114, denoted by a dashed rectangle.

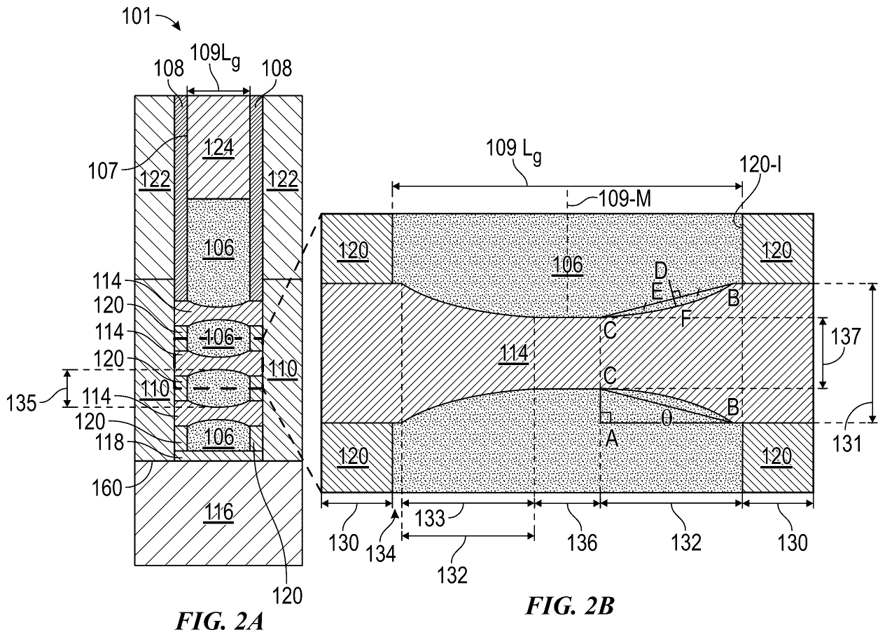

FIGS. 2A and 2B take a closer look at a GAA nanosheet transistor 101, and in particular channel layer 114, in a cross-section along the X-direction. Referring to FIG. 2A, the transistor 101 is on a semiconductor substrate 116. Sitting on an upper surface 160 of the substrate 116 and located under the gate structure 106 and gate spacers 108 is the optional self-aligned isolation layer 118. The gate structure 106 wraps around a middle portion of the stacked channel layers while an inner spacer 120 is between end portions (first region 130) of stacked channel layers 114. Source-drain regions 110 are in contact with, and flank, the channel layers' 114 first regions 130. Above the source-drain regions 110 are contacts 122. A cap dielectric 124 layer is above the gate structure 106 and can be between, and coplanar with, the gate spacers 108. The maximum distance between adjacent channel layers 114 is labeled 135.

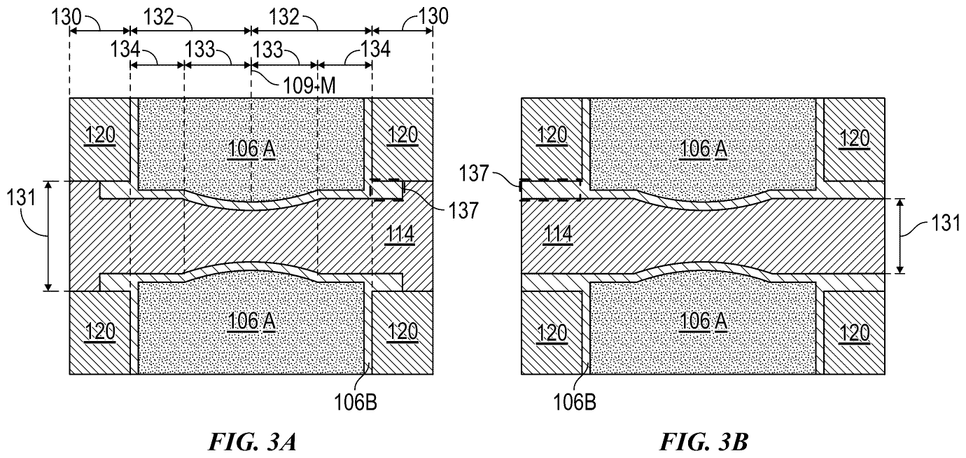

FIG. 2B is an enlargement of one of the channel layers 114 of a GAA nanosheet transistor 101 in which features of the channel layer are described. The channel layer 114 is symmetrical in shape and composition around the midpoint 109-M of the gate length 109. In one or more embodiments, the channel layer 114 has at least two regions, namely, first regions 130 located under and/or over inner spacer 120, and second regions 132 which start from the inner surface 120-I of the inner spacer 120 and are characterized by having a portion of continuous variable thickness portion 133 whose thickness decreases as the region progresses toward the gate length midpoint 109-M (i.e. the center of the gate length 109). FIG. 2B illustrates an embodiment have a third region 136 defined by a constant thickness region encompassing the gate length midpoint 109-M. The first region 130 contains the thickest region of the channel layer 114. The first region can have more than one thickness as will be demonstrated in another embodiment in connection with FIGS. 3A-3B; nevertheless, the thickest portion of the first region has a first thickness of 131.

The second region 132, in addition to the variable thickness portion 133, can optionally include an initial constant thickness portion 134 located between the first region 130 and the variable thickness portion 133. The second region 132 ends when the variable thickness 133 no longer decreases and/or reaches a constant thickness region located in or toward the center of the gate length 109 (i.e. third region 136). The constant thickness region located at the center of gate length 109 (i.e. traverses midpoint 109-M) is the third region 136. The channel layer's 114 thickness at the gate length midpoint 109-M (herein “midpoint thickness” 137) can be in the second region or third region depending upon the shape of the channel layer 114. Nevertheless, in one or more embodiments, the midpoint thickness 137 is less than first region's 130 thickness.

Still referring to FIG. 2B, the continuous variable thickness portion 133 of the second region 132 can have two embodiments. In one embodiment, continuous variable thickness portion 133 can be a facet which tapers in a straight line from its starting point to ending point (see line BC). Another embodiment is as depicted in FIG. 2B, in which the channel layer 114 is curved. To describe figures of merit of the embodiments, right triangle ABC is show in FIG. 2B. As mentioned, line BC is the straight-line embodiment of the continuously variable thickness portion 133 of the second region 132 and is the hypotenuse of triangle ABC. Point B of the triangle is located where the variable thickness begins. In embodiments with no initial constant thickness portion 134 of the second region 132, point B can be the inner sidewall 120-1 of the inner spacer 120. Point C is at the end of the second region 132. Line AB is a horizontal line from point B, making a right angle with a line dropped from point C. Line AB is the length of the variable thickness portion 133 of the second region 132 and can range from zero to half the gate length 109. In many embodiments, line AB can be a continuation of a line which defines an interface of the channel layer 114 and the inner spacer 120 in the first region 130. Line AC can represent one half of the thickness difference between the first thickness 131 and the midpoint thickness 137 and is referred to as “Delta T”. The angle theta (θ) between lines AB and BC is referred to as the nanosheet angle θ and can range from 0 to 90 degrees.

An additional figure of merit with respect to embodiments having a curved (as opposed to straight line) variable thickness portion 133 is curvature. Simplistically, curvature can be viewed as the maximum distance between the line CB (e.g. straight line embodiment) and the channel layer 114. In the FIG. 2B embodiment, this distance is shown as the line EF, a perpendicular line from CB to the curved surface of the channel layer 114. In the FIG. 2B embodiment, the shape of the curved surface is symmetric (i.e. has a constant radius of curvature) such that the line DF, which contains EF, bisects line CB. However, in embodiments in which the shape of the curved surface is not symmetric (i.e. asymmetric curvature), the curvature can be located at a point other than the midpoint of line CB. Curvature can be from >0 nm up to Delta T (e.g. line AC of FIG. 2B).

Continuing with FIG. 2B, the prior discussions described the shape of the channel layer in the first region 130, the second region 132, and the third region 136; the following discussion will describe the composition of the channel layer 114 in the different regions. In one embodiment, the first region 132, the second region 134, and the third region 136 have the same composition; for example, all undoped, or all uniformly doped silicon or silicon germanium. Alternatively, there can be a dopant gradient, less doping in first region 130 and more doping in the second 132 and/or third regions 136. Advantageously, the channel layers 114 of one GAA transistor 101 (e.g. NFET) can be all silicon while channel layers 114 of another transistor 101 (e.g. PFET) can be all silicon germanium. In other embodiments, the first regions 130 of the channel layers 114 can be one composition while the second 132 and optional third regions 136 have another composition. For example, the first regions 130 can be silicon while the other regions can be silicon germanium. In yet another embodiment, the first regions 130 can have a first composition, the second regions 132 can have a second composition, and the third region 136 can have a third composition. For example, the first regions 130 can be silicon while the second regions and the third region can both be silicon germanium, but can have different germanium concentrations. Advantageously, the third region 136 has a higher germanium concentration than the second regions 132.

Turning to FIGS. 3A-3B, another embodiment of the channel layers 114 in a GAA transistor 101 is illustrated. Similar to FIG. 2B, FIGS. 3A-3B focuses on the channel layer 114 of the transistor 101 embedded in the gate structure 106. In FIGS. 3A and 3B, the gate structure includes gate conductors 106A (i.e. workfunction and metal gate) and gate dielectrics (e.g. interfacial layer and high-k dielectric) 106B. Here, an expanded gate cavity 137 between at least a portion of the first region 130 of the channel layer 114 and the inner spacer 120 is filled with gate dielectrics (e.g. interfacial layer and high-k dielectric) 106B. By filling the expanded cavity 137 with gate dielectrics 106B, gate conductors 106A are prevented from entering the expanded cavity 137, thereby reducing capacitance and recovering drain induced barrier lowering (“DIBL”). In FIG. 3A, the expanded gate cavity 137 only partially penetrates under the inner spacer 120, creating a stepped first region 130, which maintains the first region thickness 131 relative to embodiments without an expanded gate cavity 137. However, in FIG. 3B, the expanded gate cavity 137 fully penetrates under the inner spacers 120, thereby reducing the thickness 131 in the first region 130 relative to its original thickness. Also to note, in the FIGS. 3A and 3B, an embodiment is shown that lacks a third region 136 (i.e. constant thickness region including midpoint 109-M), is illustrated by way of example and not limitation. The embodiment illustrated in FIGS. 3A-3B, the second region 132 starts with a constant thickness portion 134, moves into the continuously varying thickness portion 133 to it reaches a minimal thickness at the midpoint 109-M where the thickness begins to increase in the second region 132 going to the opposite inner spacer 120. It should be noted that the disclosure contemplates that the embodiments of FIGS. 3A-3B could also include a third region 136 (i.e. constant thickness region including midpoint 109-M). Conversely, the disclosure contemplates that the embodiments of FIGS. 2A-2B could lack a third region 136 (i.e. constant thickness region including midpoint 109-M).

The next series of figures illustrate methods of making various embodiments. Here, referring to FIG. 1, “A” views are along active area fin 102 of a transistor 101 (e.g. NFET) in the X1 direction, “B” views are along active area fin 102 of a transistor 101 (e.g. PFET) in the X2 direction, “C” views cross adjacent fins 102 in the Y1 direction, and “D” views run along gate structure 106 in the Y2 direction.

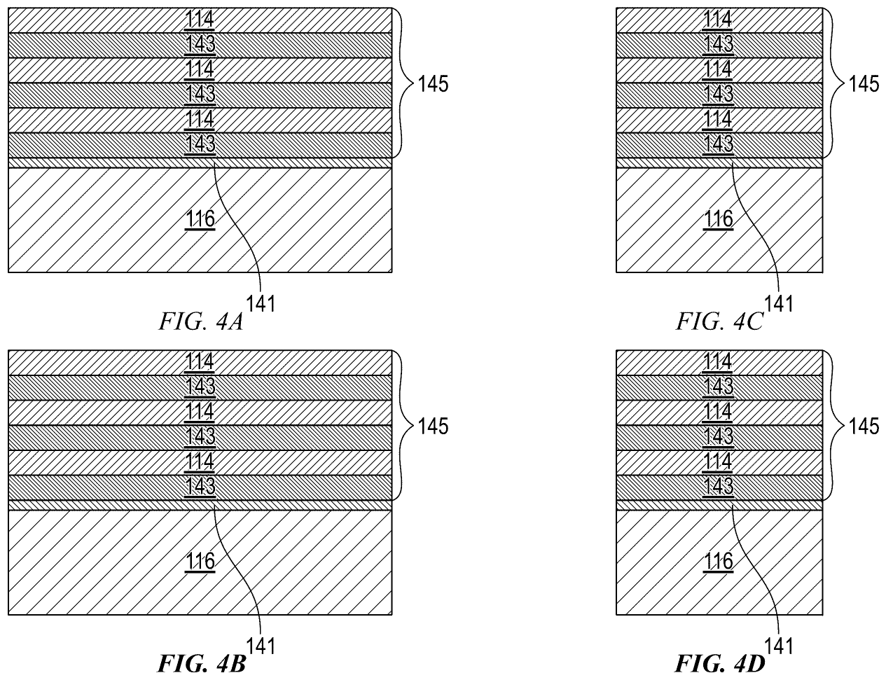

FIGS. 4A-4D are a starting point of making an embodiment having a self-aligned isolation layer 118 (discussed in connection with other figures). Here, a bottom sacrificial layer 141 is formed on a substrate 116. On top of the bottom sacrificial layer 141, a nanostack 145 of alternating layers of sacrificial material 143 and channel layers 114 is formed. The original thickness of each layer of the sacrificial material 143 and channel layers 114 can be in the high single digit to low double digit nanometer range. The bottom sacrificial layer 141 is advantageously thinner than each alternating layer of the stack. Both the bottom sacrificial layer 141 and the alternating layers of sacrificial material 143 can be silicon germanium but have different germanium concentrations to the extent appropriate for the bottom sacrificial layer 141 to be etched selectively relative to the layers of sacrificial material 143, and for the sacrificial layers 143 to be etched selectively relative the channel layers 114. The channel layer 114 can be silicon doped as appropriate for an NFET or PFET. All layers can be epitaxially grown. Here, all views are the same as no patterning has taken place.

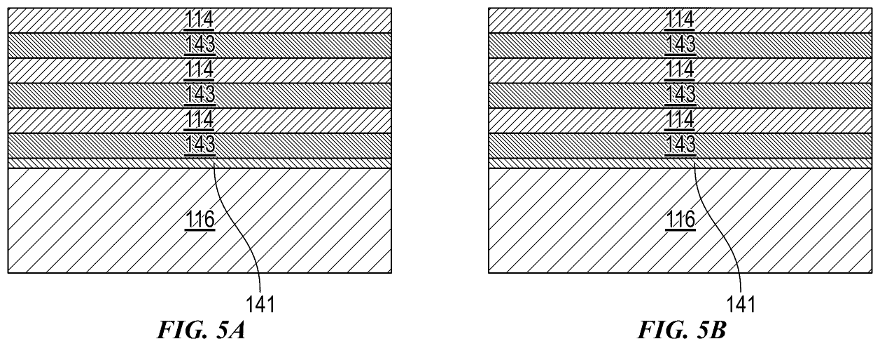

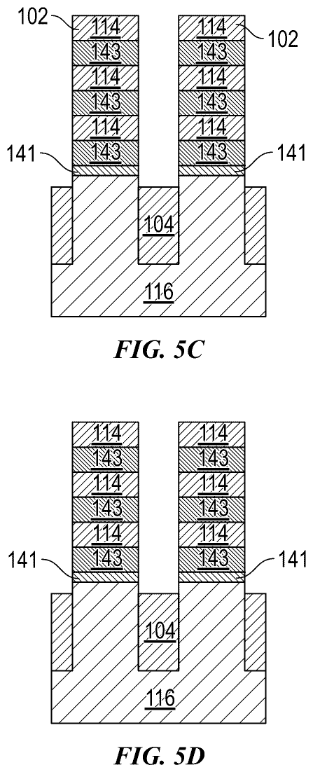

In FIGS. 5A-5D, the blanket nanosheet stacks 145, bottom sacrificial layer 141 and substrate 116 are etched to form fins 102 and shallow trenches in the substrate. The shallow trench isolation region 104 can be filled with a silicon oxide-based dielectric layer.

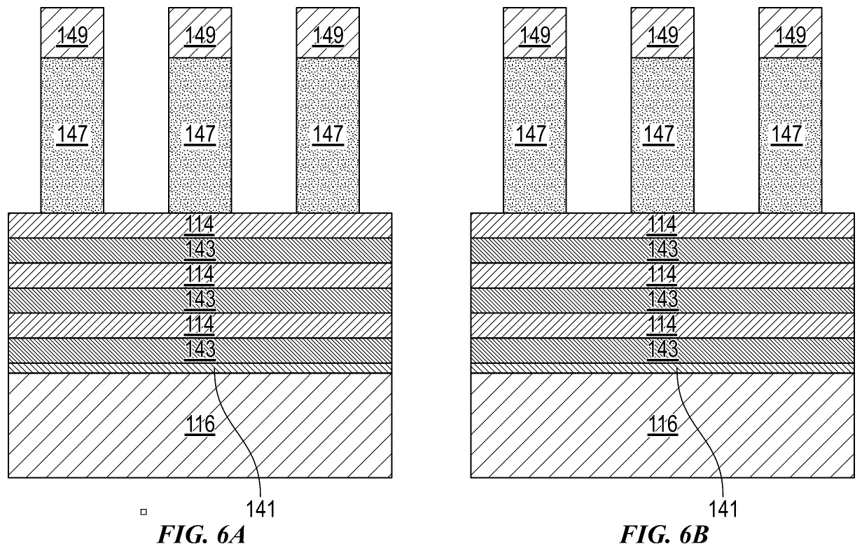

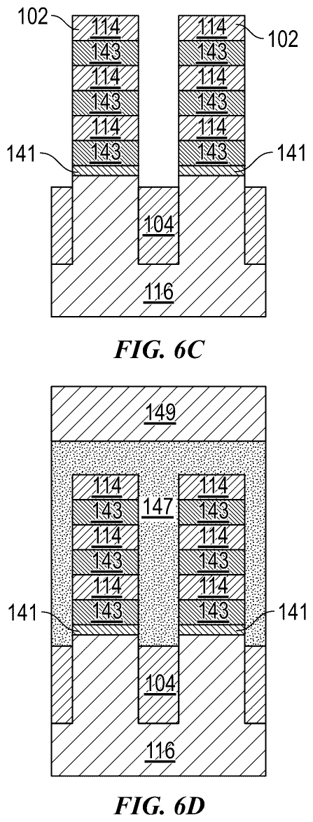

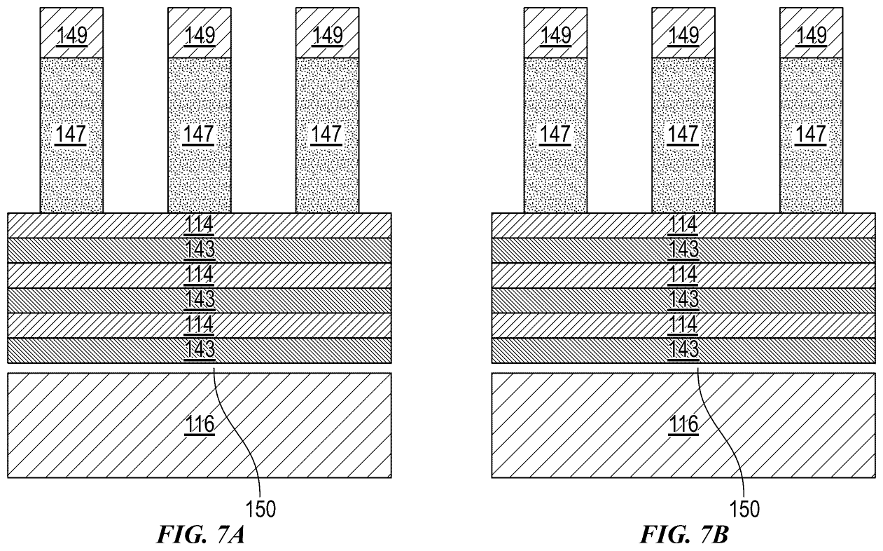

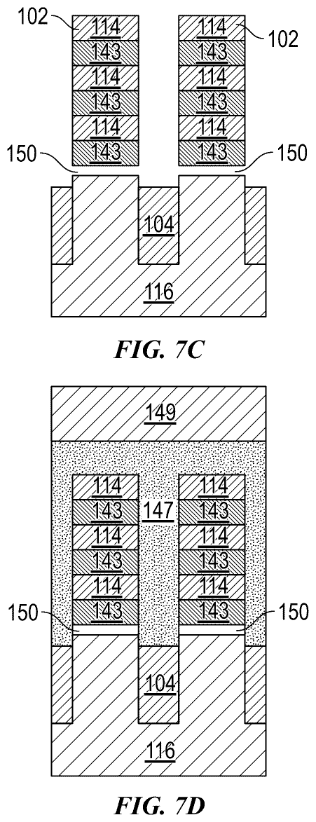

In FIGS. 6A-6D, dummy gate material and a hardmask 149 are deposited and patterned to form dummy gates 147. The dummy gate material can be amorphous silicon. Referring to FIGS. 7A-7D, with patterned dummy gate 147 material in place, the bottom sacrificial layer 141 is selectively removed to leave a bottom cavity 150.

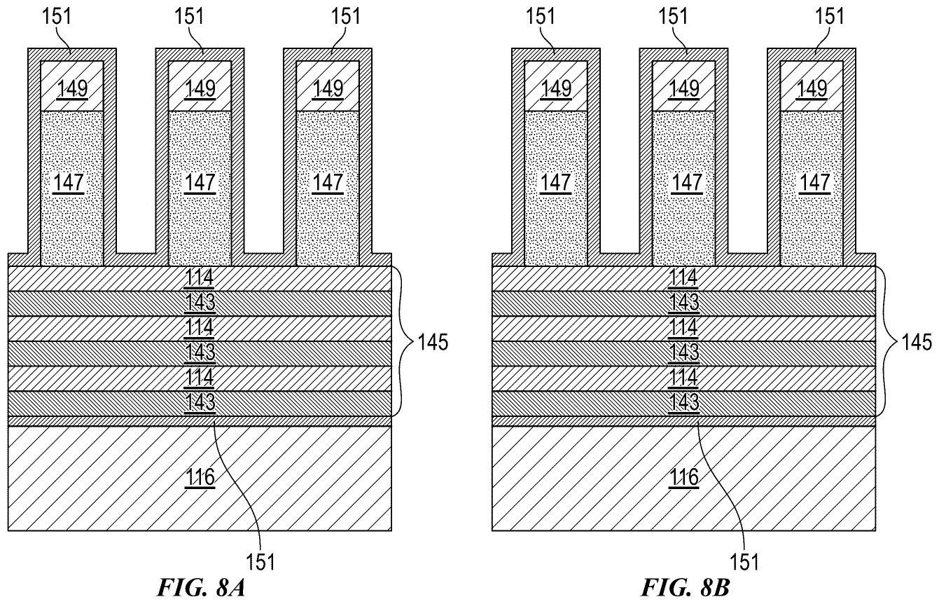

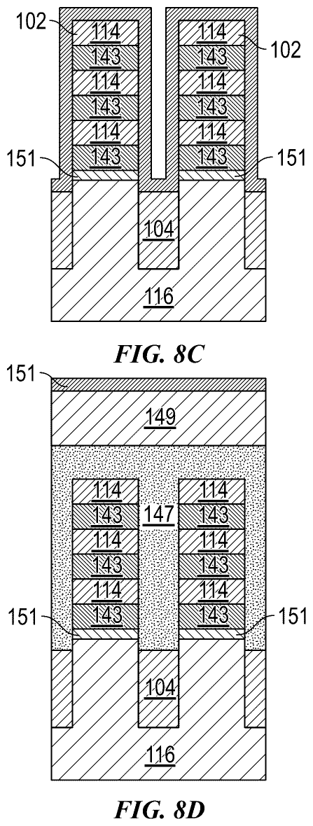

In FIGS. 8A-8D, a conformal deposition of an insulating material 151 takes place, which surrounds the dummy gates 147 and hardmask 149, and fills the bottom cavity 150.

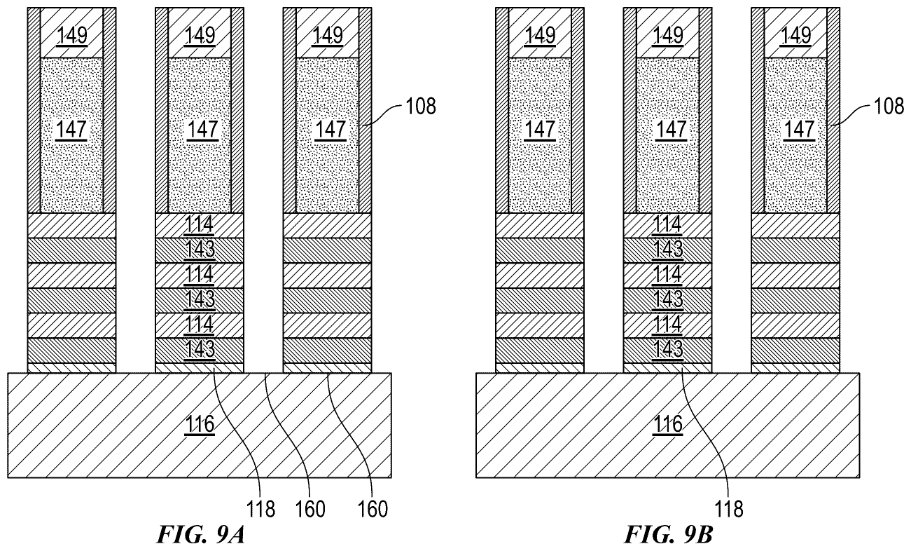

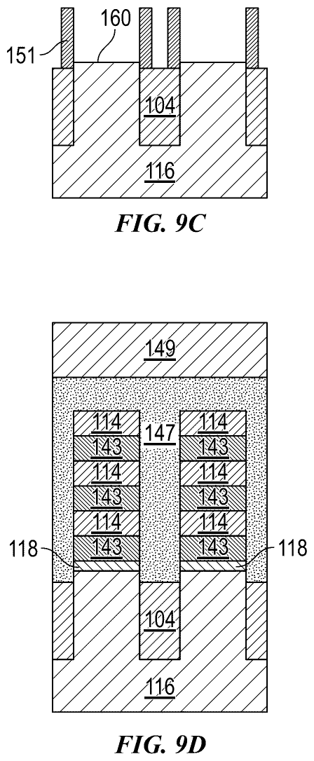

In FIGS. 9A-9D, the insulating material 151 is then anisotropically etched to form first and second gate spacers 108 on either side of each dummy gate 147 and to form the self-aligned isolation layer 118 between the substrate 116 and nanostack 145. Thus, the gate spacers 108 and the self-aligned isolation layer 118 are made from the same material, which can be a nitride containing dielectric or other suitable material.

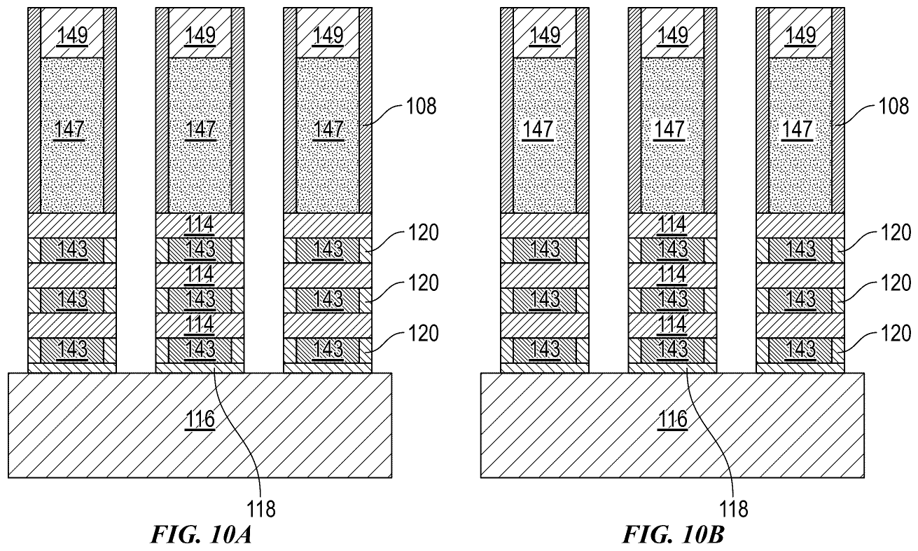

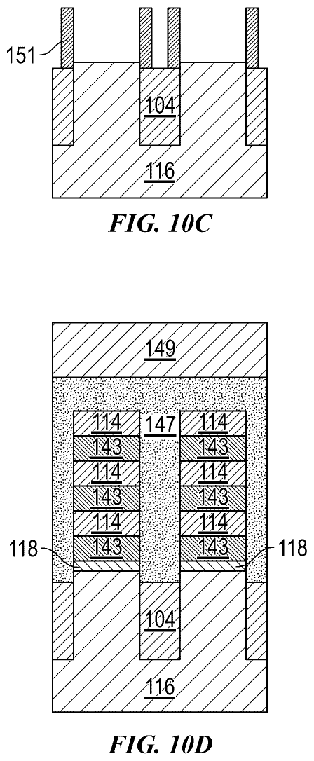

In FIGS. 10A-10D, exposed end surfaces of sacrificial material 143 are recessed, leaving cavities that are filled with a dielectric and recessed, thereby forming inner spacers 120 over and/or under first regions 130 of each channel layer 114.

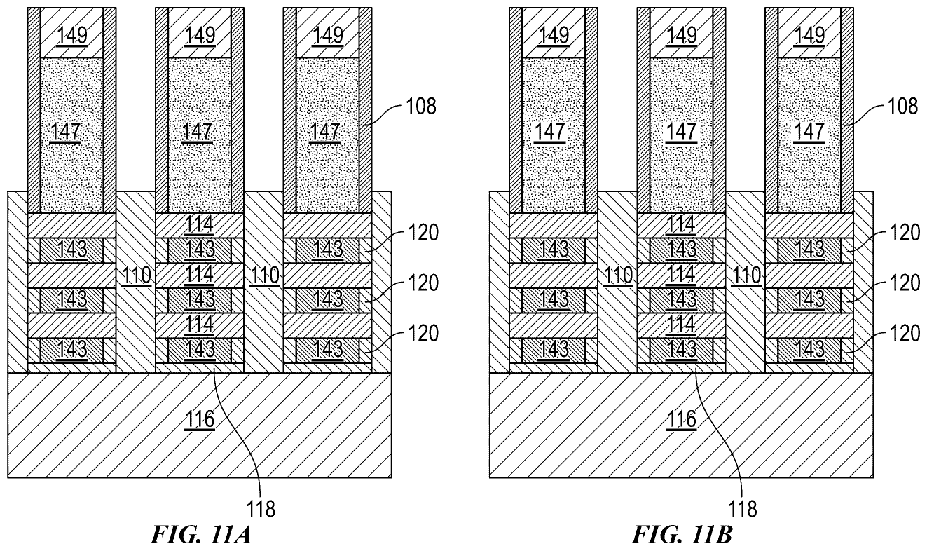

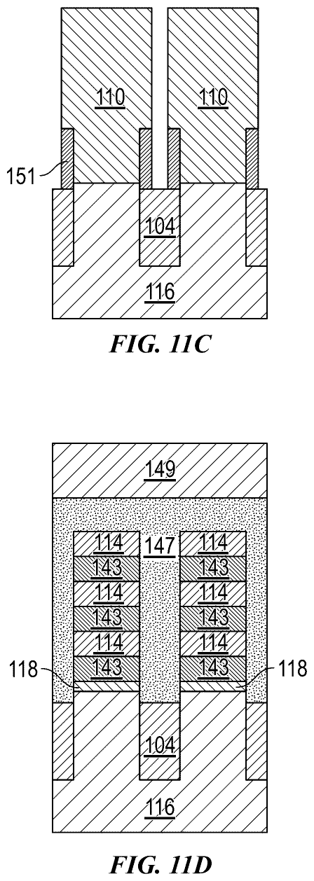

In FIGS. 11A-11D, source-drain regions 110 are epitaxially grown with doping appropriate for the polarity of the transistor. The source-drain regions 110 are in contact with the first regions 130 of the channel layers 114 and substrate 116.

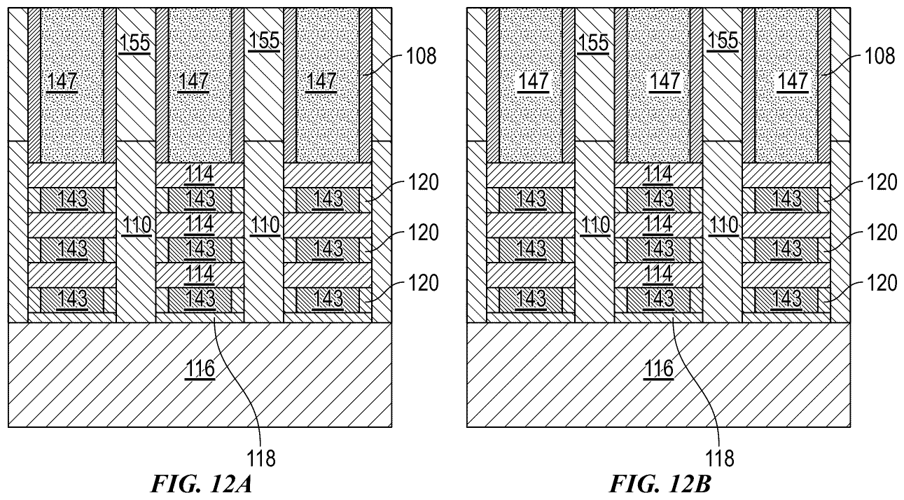

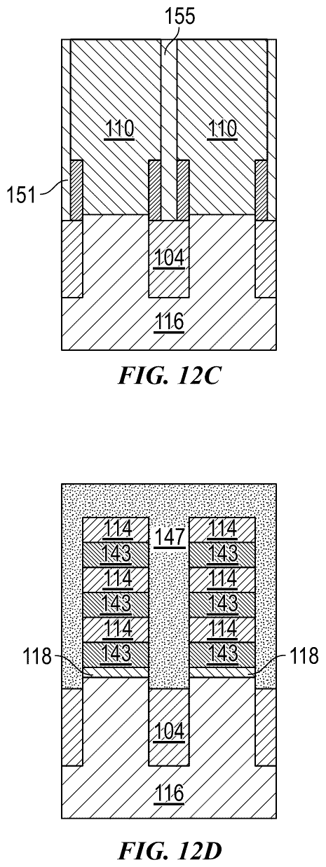

In FIGS. 12A-12D, a middle of the line dielectric layer 155 is deposited and planarized to expose, and be co-planar with, the dummy gate 147, gate spacers 108 (referring to FIGS. 12A and 12B) and source-drain regions 110 (referring to FIG. 12C).

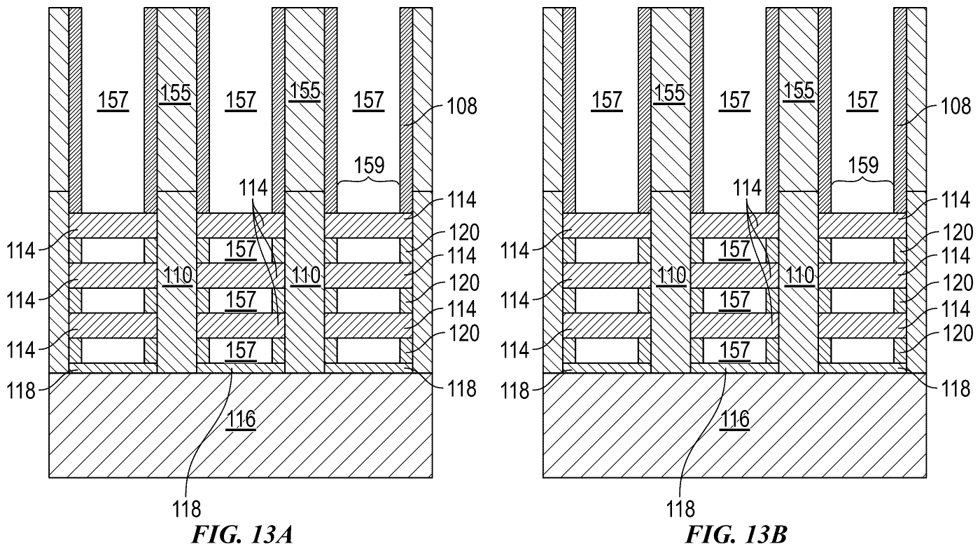

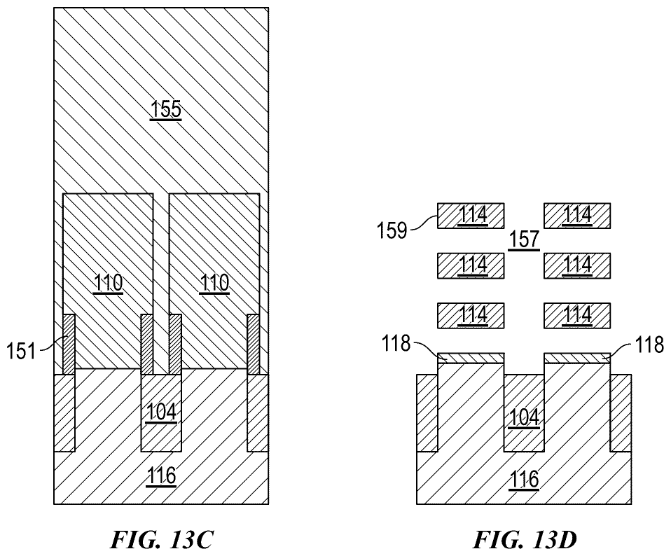

In FIGS. 13A-13D, dummy gate 147 material is removed by a selective process to leave a gate cavity 157 between gate spacers 108 (referring to FIGS. 12A and 12B) and source-drain regions 110 (referring to FIG. 12C). In addition, the layers of sacrificial material 143 are removed from the nanostack 145. The combined removals leave exposed portions 159 of the channel layers 114.

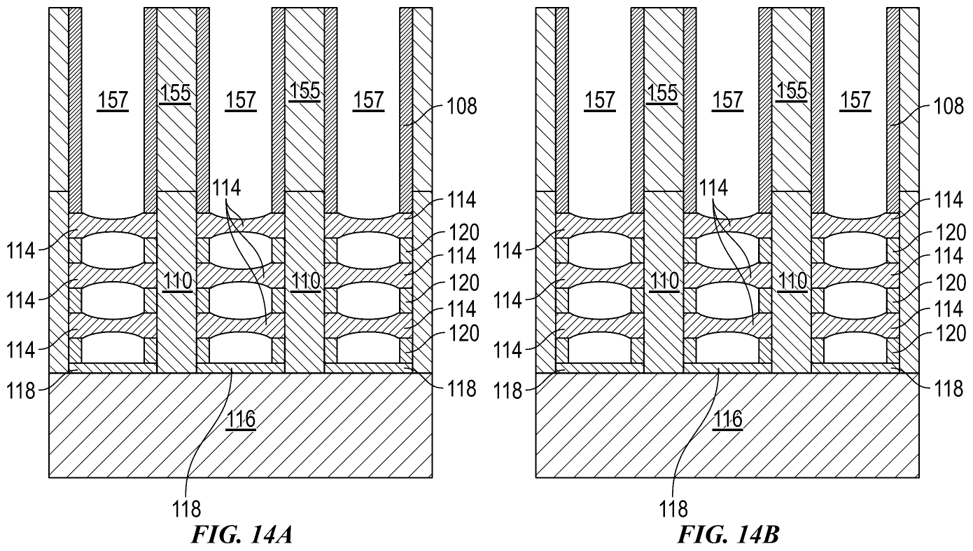

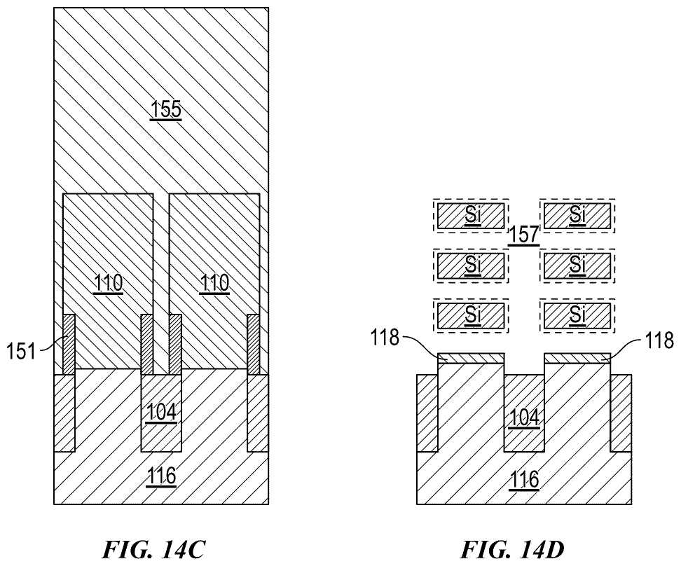

In FIGS. 14A-14D exposed portions 159 of the channel layer 114 are trimmed to from the variable thickness regions discussed in conjunction with FIGS. 2A-2B. The dotted line represents the original thickness of the channel layer 114 prior to trimming. A non-limiting example of the trimming process includes: cycles of controlled silicon oxidation combined with selective isotropic etch of SiO. Furthermore, the embodiments of FIGS. 3A-3B can be achieved by leveraging a crystallographic etch exhibiting etch rates dependent on the crystallographic orientation of the semiconductor channel. This etch rate dependency can be functionalized to trim the semiconductor channel thickness in the vertical direction while controlling the lateral overetch amount in first region 130 of the channel layers 114, thereby forming the expanded gate cavity 137 located in extension regions (under inner spacers). A non-limiting example of the trimming process includes: cycles of controlled silicon oxidation combined with selective isotropic etch of SiO.

After trimming, the exposed and trimmed channel layers 114 in one or more transistors 101 can be clad in silicon germanium and then annealed to diffuse germanium into the channel layer 114. By varying the cladding concentration of germanium, thickness of cladding SiGe, thickness of channel layer 114 regions, annealing conditions, and/or channel trimming conditions (selectivity to Si and SiGe) the various germanium concentrations previously described in the first, second and third channel regions can be obtained. In an embodiment, cladding is advantageously applied to PFET transistors. Optionally, the first region 130 can have the highest germanium concentration, the second region 132 can have a lower germanium concentration and the third region 136 can have the least germanium concentration.

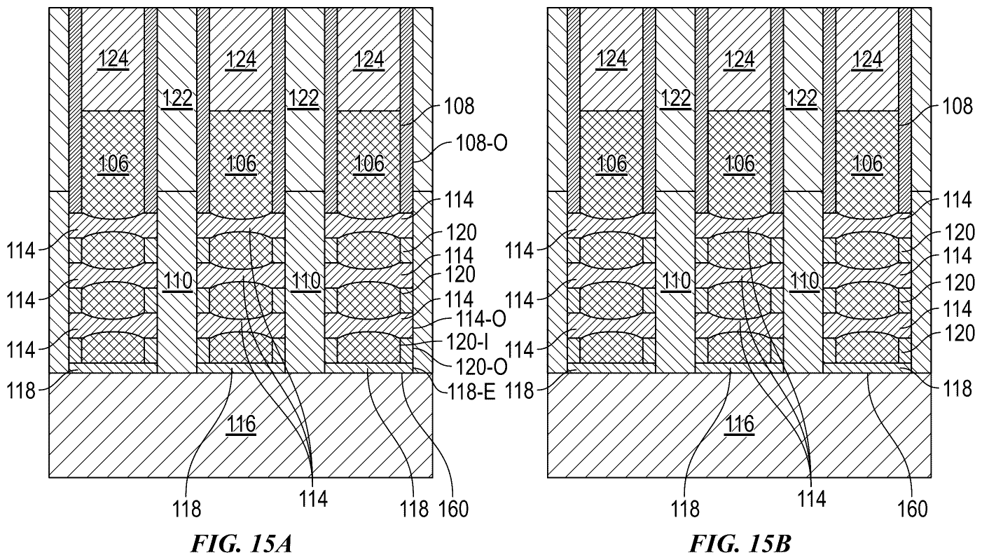

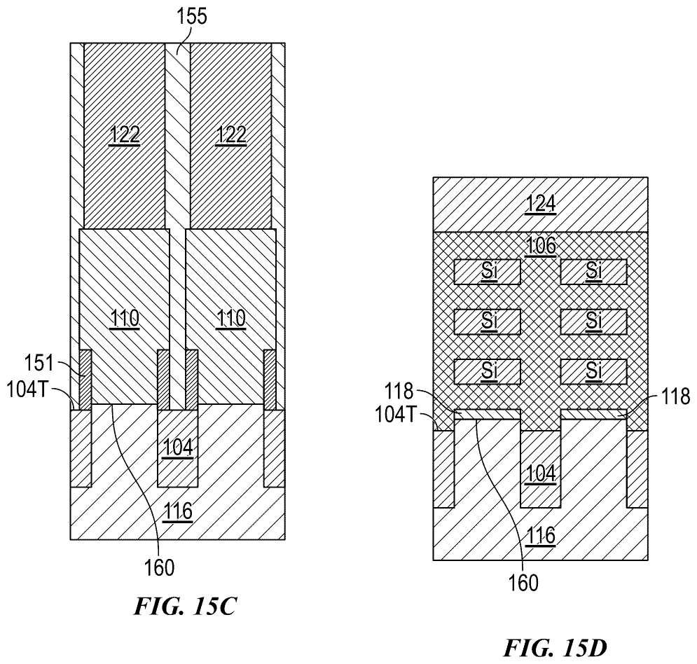

In FIGS. 15A-15D, contacts 122 are made to the source-drain regions 110 to complete the device. While not shown, one skilled in the art will realize an additional contact 122 is also made to the gate structure 106. Note, due to the presence of the self-aligned isolation layer 118, the upper surface 160 of the substrate 116 is flat under adjacent gate structure 106, gate spacer 108 and source-drain region 110 (see FIGS. 15A-15B). Also note, the upper surface 160 of the substrate 116 is proud of the top surface 104T of the shallow trench isolation region 104 (see FIGS. 15C-15D). Referring to FIGS. 15A-15B, the self-aligned isolation layer 118's bottom surface is in contact with the top surface 160 of the substrate, while its top surface is in contact with the gate structure 106 and a bottom surface of the inner spacer. An edge surface 118E of the self-aligned insulation layer 118 is vertically aligned with outer surface (120-O, 114-O or 108-O, respectively) of one or more of the inner spacer 120, channel layer 114 or gate spacer 108.

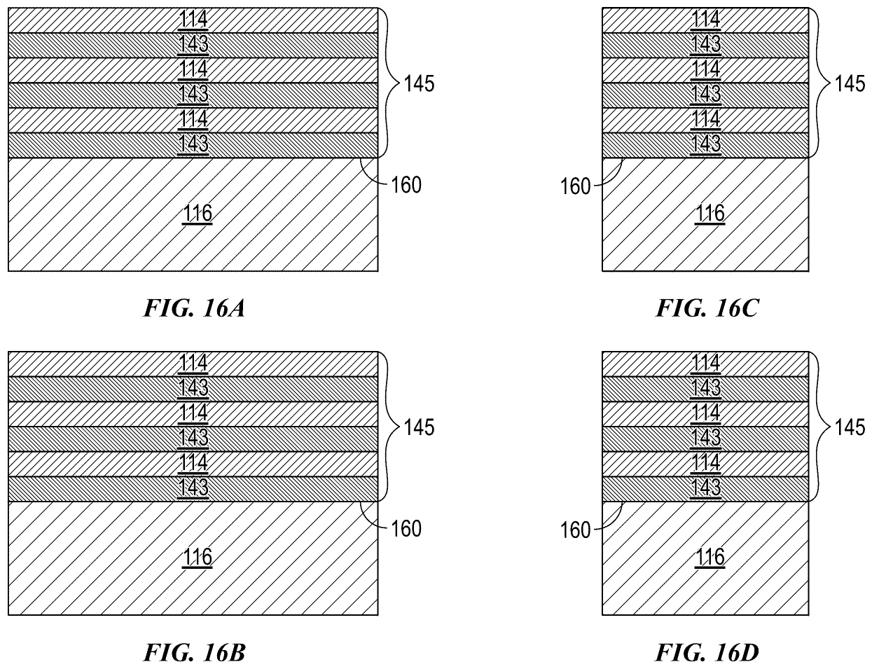

FIGS. 16A-16D are a starting point of making an embodiment lacking self-aligned isolation layer 118. In contrast, to FIGS. 4A-4D, the nanostack 145 is grown and sits directly on an upper surface 160 of the substrate 116.

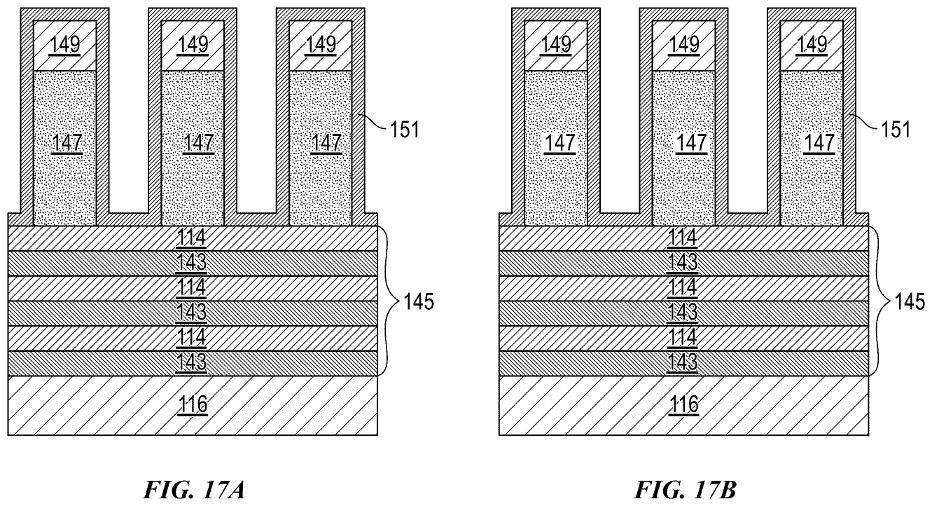

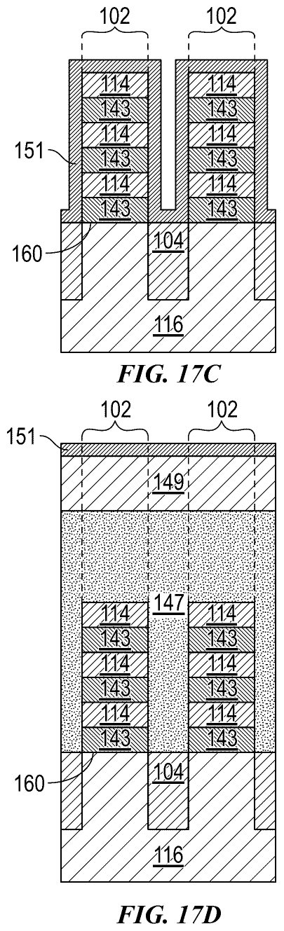

In FIGS. 17A-17D, the nanostacks 145 and substrate 116 are etched to form fins 102 and shallow trench cavities between the fins 102 which are filled with insulator to form shallow trench isolation regions 104. Comparing the embodiment of FIGS. 17C-17D with FIGS. 5C-5D (an analogous point in the process of the self-aligned isolation layer 118 embodiment described in FIGS. 4A-16D), in the current embodiment lacking the self-aligned layer 118, an upper surface of the shallow trench isolation region 104 is coplanar with the upper surface 160 of the substrate 116. However, in the self-aligned layer embodiment of FIGS. 5C-5D, at this point in the method, the upper surface of the shallow trench isolation region 104 is below the upper surface 160 of the substrate 116 located under the nanostack fin 102.

Continuing with FIGS. 17A-17D, dummy gate 147 material and hardmask 149 are deposited and etched. Subsequently, insulating material 151 is conformally deposited over the entire structure. Comparing the embodiment of FIGS. 17A-17D with FIGS. 8A-5D (an analogous point in the process of the self-aligned isolation layer embodiment described in FIGS. 4A-16D), in the current embodiment lacking the self-aligned layer 118, insulation material 151 is not between the substrate 116 and the nanostack 145.

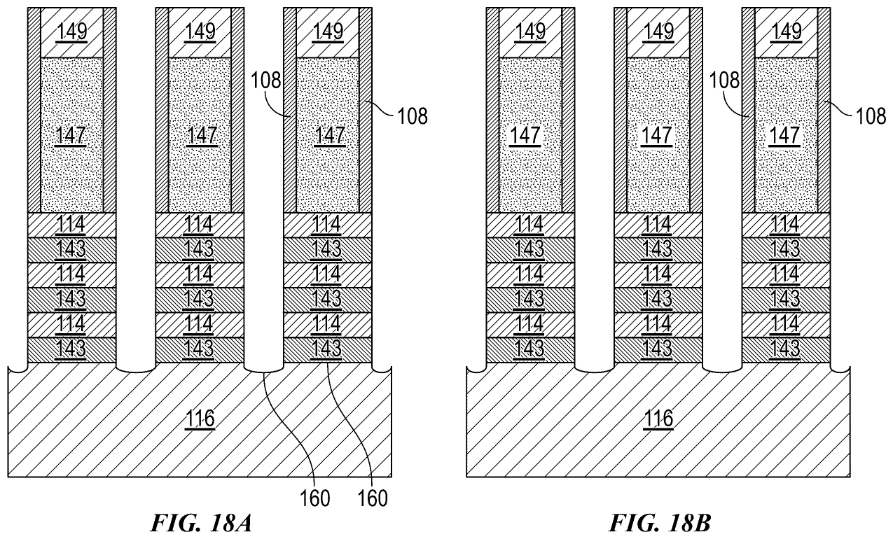

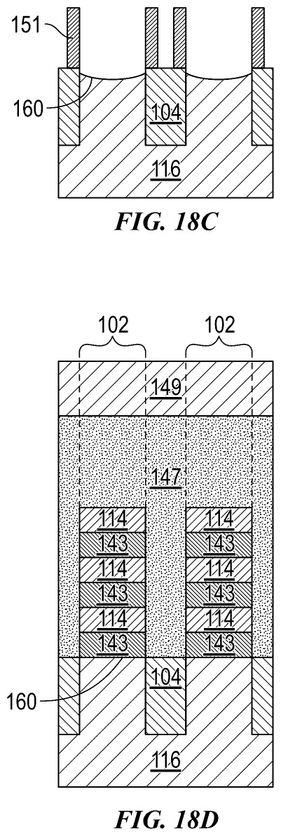

Referring to FIGS. 18A-18D, the insulation material 151 is anisotropically etched to form first and second gate spacers 108 on either side of the dummy gate 147. In addition, a fin recess etch is performed to remove nanostack material between the dummy gate 147/gate spacer 108 structures. Note, due to the lack of a self-aligned isolation layer 118, the upper surface 160 of substrate 116 is etched, creating divots between the shallow trench isolation regions 104 (FIG. 18C) and between dummy gate structures (FIGS. 18A-18C). Compare to FIGS. 9A-9D of the self-aligned isolation layer 118 embodiment, in which in analogous figures, the upper surface 160 of the substrate 116 lacks divots.

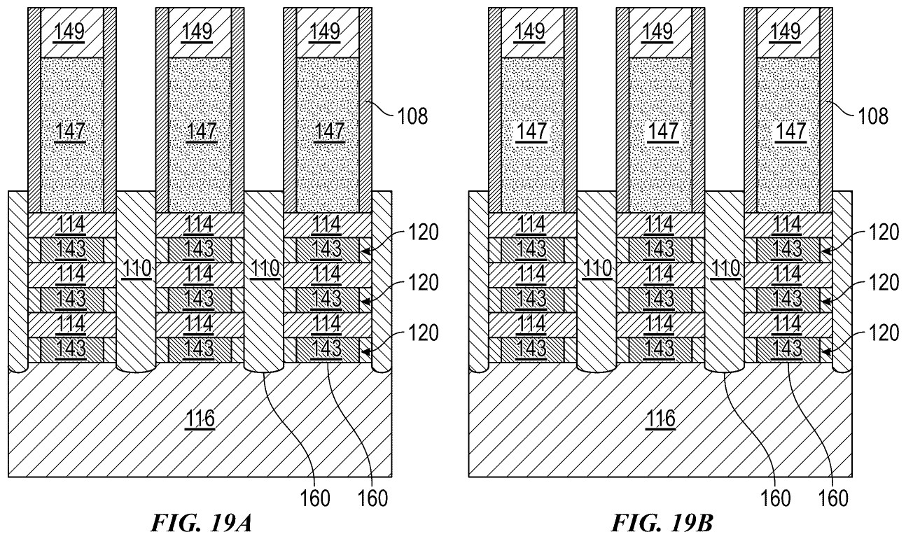

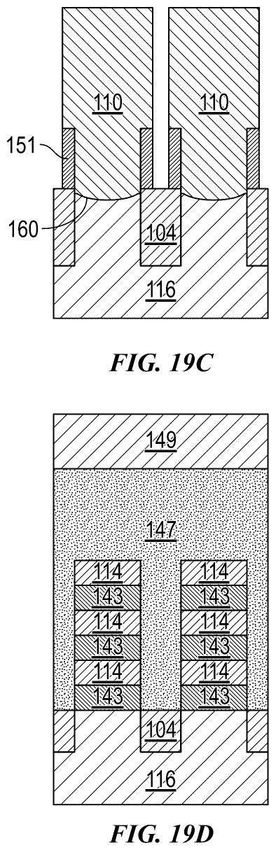

Referring to FIGS. 19A-19D, the sacrificial material 143 of the nanostack 145 is recessed to leave cavities, which are filled with an insulator, resulting in inner spacer 120 formation. In addition, source-drain materials are grown on the exposed upper surfaces 160 of the substrate 116 and on exposed surfaces of the channel layer 114.

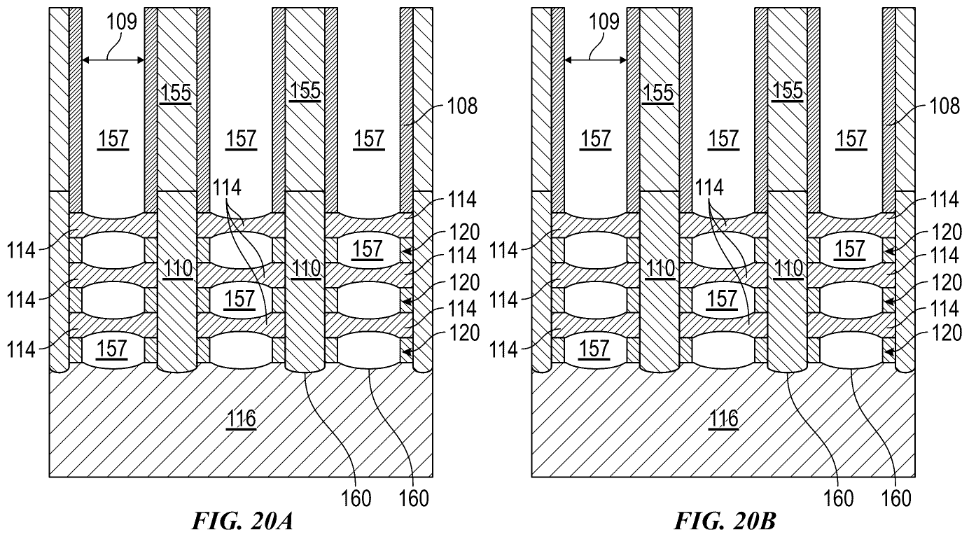

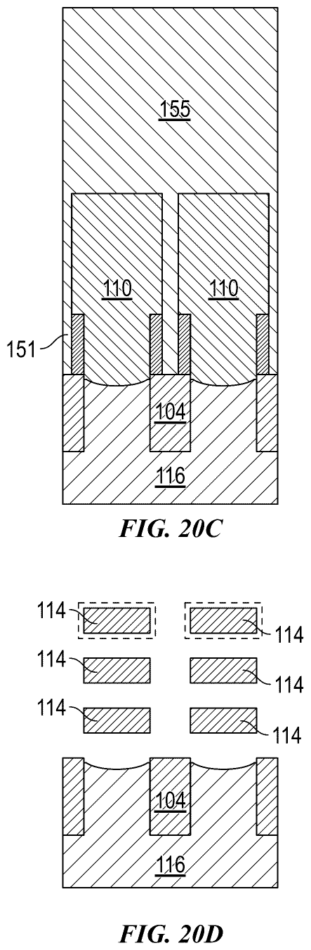

Referring to FIGS. 20A-20D, a middle of the line dielectric layer 155 is deposited and planarized to be co-planar with the dummy gate 147. The exposed dummy gate 147 is then removed as is the sacrificial material 143 of the nanostack. The result is gate cavities 157 which expose the substrate 116 and channel layers 114. The channel layers are then trimmed (see dotted lines of FIGS. 20A, B and D) to form the previously described channel layers 114 having variable thickness. Note, that at the end of the various etches, the upper surface 160 of the substrate 116 under the gate length 109, also has a divot.

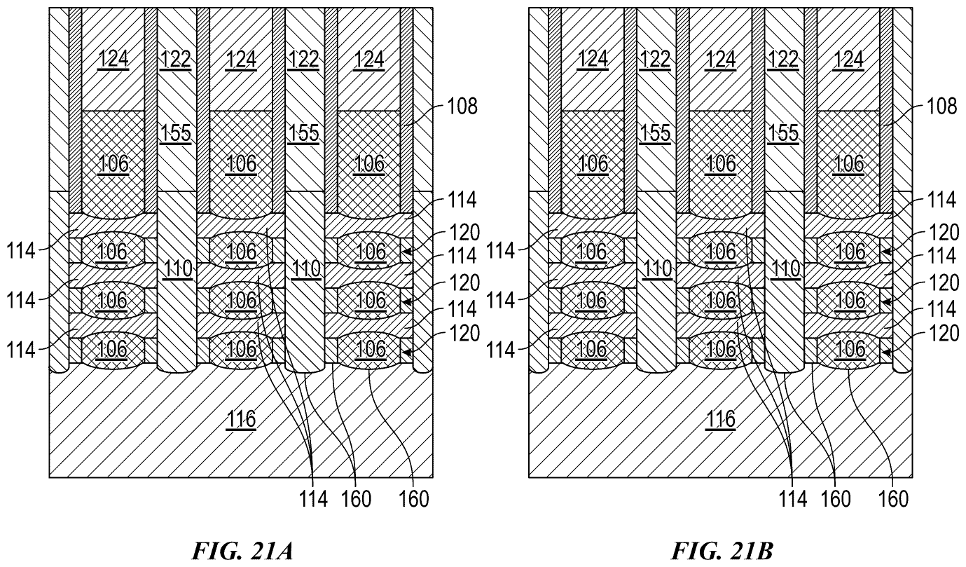

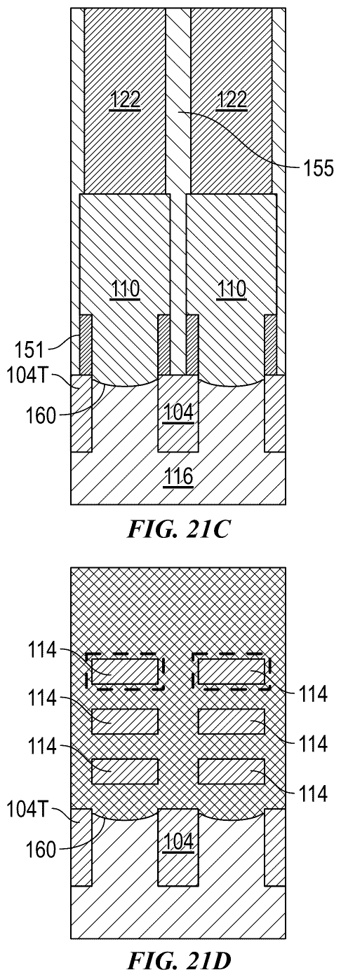

Referring to FIGS. 21A-21D, the gate structure 106 is formed by depositing gate dielectrics (including interfacial layer and high-k dielectric) and gate conductors (including workfunction and metal fill). Cap dielectric layer 124 and contacts 122 are as described in FIGS. 15A-15D. A pertinent difference of the final structure of the current embodiment of FIGS. 21A-21D and the prior embodiment of FIGS. 15A-15D, is that the lack of self-aligned isolation layer 118 in FIGS. 21A-21D results in a top surface 160 of the substrate 116 having divots (i.e. being recessed) under the gate structure 106 and source-drain regions 110 relative to the upper surface 160 of the substrate 116 under the gates spacer and relative to the top surface 104T of the shallow trench isolation region 104.

Semiconductor device manufacturing includes various steps of device patterning processes. For example, the manufacturing of a semiconductor chip can start with, for example, a plurality of CAD (computer aided design) generated device patterns, which is then followed by effort to replicate these device patterns in a substrate. The replication process can involve the use of various exposing techniques and a variety of subtractive (etching) and/or additive (deposition) material processing procedures. For example, in a photolithographic process, a layer of photo-resist material can first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) can experience some changes in their solubility to certain solutions. The photo-resist can then be developed in a developer solution, thereby removing the non-irradiated (in a negative resist) or irradiated (in a positive resist) portions of the resist layer, to create a photo-resist pattern or photo-mask. The photo-resist pattern or photo-mask can subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method can utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for case of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose may be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A gate-all-around transistor comprising:
a gate structure having sidewalls;
a first and a second gate spacer positioned laterally on each sidewall, wherein the gate structure has a gate length between the sidewalls of the gate structure, the gate length having a midpoint;
a first inner spacer under the first gate spacer;
a second inner spacer under the second gate spacer;
a channel layer extending from below the first inner spacer, across the gate length to below the second inner spacer, the channel layer comprising:
a first region having a first thickness and located below each of the gate spacers; and
a second region having a continuously variable thickness, the second region located laterally between the first regions and being symmetrical in reference to the midpoint of the gate length.

2. The transistor of claim 1, wherein the channel layer further comprises a third region having a third thickness less than the first thickness, the third region being located at a midpoint of the gate length, with each end of the third region being laterally adjacent the second region, the third region having a non-variable thickness.

3. The transistor of claim 2, wherein a length of the second region is 49% to 2% of the gate length.

4. The transistor of claim 2, wherein a curvature of the second region is 0 to 90 degrees.

5. The transistor of claim 2, wherein the first region, the second region and the third region are a same material.

6. The transistor of claim 5, wherein the same material is silicon.

7. The transistor of claim 5, wherein the same material is silicon germanium having uniform germanium concentration.

8. The transistor of claim 5, wherein in the same material is silicon germanium having variable germanium concentrations.

9. The transistor of claim 8, wherein a concentration of germanium in the first region is less than concentration of germanium in the third region.

10. The transistor of claim 2, wherein the first region is silicon and wherein the second and third regions are silicon germanium.

11. The transistor of claim 10, wherein a germanium concentration in the third region is greater than the germanium concentration in the second region.

10. The transistor of claim 10, wherein germanium concentration in the third region is equal to the germanium concentration in the second region.

13. The transistor of claim 1, wherein the gate structure comprises a gate conductor, and a gate dielectric; and
wherein the gate structure wraps the channel layer exposed in the gate length.

14. The transistor of claim 13, further comprising:
an inner spacer located under the first region of the channel layer, wherein the gate dielectric is between the inner spacer and the first region of the channel layer.

15. The transistor of claim 1, further comprising:
a flat portion of the second region, wherein the flat portion contacts the first region of the channel layer while the continuously variable thickness of the second region is in contact with the flat portion.

16. The transistor of claim 1, further comprising:
a substrate having an upper surface;
a source-drain region on either side of the channel layer;
an inner spacer comprising:
an outer surface in contact with the source-drain region and located under each of the gate spacers; and
an inner surface in contact with the gate structure;
a self-aligned isolation layer having a top surface, a bottom surface and edge surface, wherein the top surface is in contact with the inner spacer and the gate structure, the bottom surface is in contact with the upper surface of the substrate, and the edge surface is vertically aligned with the outer surface of the inner spacer;
a second transistor; and
a shallow trench isolation region separating the transistor and the second transistor;
wherein the second transistor comprises;
a second self-aligned isolation layer; and
a second gate structure;
wherein a top surface of the second self-aligned isolation layer is in contact with the second gate structure and the bottom surface is in contact with the upper surface of the substrate, and
wherein the upper surface of the substrate is higher than a top surface of the shallow trench isolation region.

17. A method of forming a semiconductor structure, comprising:
forming a nanostack on a substrate wherein each nanostack comprises a plurality of alternating layers of a sacrificial material and a channel layer;
etching the nanostack to form at least two adjacent, parallel nanostack fins;
forming a shallow trench isolation region in the substrate and between the nanostack fins;
forming a dummy gate fin over and perpendicular to the nanostack fins;
forming a gate spacer around the dummy gate fin to create an exposed portion of the substrate;
removing portions of the sacrificial material in the nanostack fins to create a recess;
forming an inner spacer in the recess;
forming source-drain regions on the exposed portion of the substrate on either side of the dummy gate fin and in contact with the channel layer;
forming a planarized middle of the line dielectric layer over the substrate;
removing the dummy gate fin and the sacrificial material remaining in the nanostack fin to create a gate cavity resulting in an exposed portion of the channel layer;
trimming the exposed portion of the channel layer in the gate cavity to create a first region of the channel layer under the inner spacer, a second region of the channel layer laterally in contact with the first region and having a curvature, and a third region of the channel layer laterally in contact with the second region, wherein a first region thickness of the channel layer is greater a third region thickness of the channel layer;
forming a gate structure in the gate cavity; and
forming contacts to the source-drain region and a gate structure.

18. The method of claim 17, wherein the nanostack further comprises a bottom sacrificial layer in contact with the substrate, further comprising:
removing the bottom sacrificial layer to form a bottom cavity below the nanostack fins and above the substrate; and
wherein forming the gate spacers includes filling the bottom cavity with a gate spacer material and etching the gate spacer material to form a self-aligned isolation layer between the nanostack fin and the substrate.

19. The method of claim 17, further comprising:
removing a portion of the channel layer from under the inner spacers to form an expanded gate cavity; and
forming a gate dielectric in the expanded gate cavity.

20. The method of claim 17, further comprising:
after trimming the channel layer, converting at least a portion of the channel layer in a first nanostack fin to silicon germanium while the channel layers in a second nanostack are masked.
